(19) United States
(12) Patent Application Publication
(10) Pub. No.: US 2024/0274454 A1
(43) Pub. Date: Aug. 15, 2024

(54) SUBSTRATE CONTAINER SYSTEMS AND METHODS OF PURGING A SUBSTRATE CONTAINER

(71) Applicant: ENTEGRIS, INC., Billerica, MA (US)

(72) Inventors: Ryan Madhu Jacob, Colorado Springs, CO (US); Matthew A. Fuller, Colorado Springs, CO (US); Mark V. Smith, Colorado Springs, CO (US); Aleksandr Anatoliyvich Yakuba, Colorado Springs, CO (US); Colton J. Harr, Monument, CO (US)

(21) Appl. No.: 18/438,258

(22) Filed: Feb. 9, 2024

Related U.S. Application Data
(60) Provisional application No. 63/444,685, filed on Feb. 10, 2023.

(51) Int. Cl. H01L 21/673

(52) U.S. Cl. CPC H01L 21/67389

(57) ABSTRACT

Described are support devices that are useful with substrate containers used to hold or transport substrates in a clean environment, as well as associated systems and methods of using the support devices and substrate containers.

### FIELD

The present disclosure relates to support devices that are useful with substrate containers used to hold or transport substrates in a clean environment, as well as associated methods of using the support devices and substrate containers.

### BACKGROUND

Microelectronic devices are prepared on semiconductor substrates by a series of precise processing steps, each being performed under exceedingly clean conditions. Between processing steps, a “substrate” onto which the microelectronic devices are being formed may be moved from one processing location to a different processing location.

To move substrates between processing steps or separate processing locations, the substrates are held in a specialized container that is designed to prevent the substrates from being damaged, while also shielding the substrates from contamination. Example substrate containers may be referred to as “SMIF pods” (Standard Mechanical Interface pods), “FOUPs” (Front Opening Unified Pods), or “FOSBs” (Front Opening Shipping Box). During use, these containers enclose a space to contain multiple semiconductor wafers or other substrates within an atmosphere that may be evacuated (i.e., that is under reduced pressure) or that may contain a gas that is different from air, e.g., an inert gas.

A substrate container may be in the form of a multi-sided container body (e.g., a “shell”) that defines a container interior. The container body includes an opening on one side that allows multiple substrates to be inserted into the interior or removed from the interior. Example containers also include a removable door that is adapted to cover the opening to enclose the interior with an air-tight seal. The container also includes one or more gas ports (one or more inlets or optional outlets) that pass through a bottom of the container to allow gases to be introduced into the interior and removed (e.g., “purged”) from the interior, to control the atmosphere within the container. The gas ports align with nozzles of a separate piece of equipment, which may be referred to as a “substrate container support” (or “support plate” or a “purge plate”) of a load port apparatus. During a step of purging the interior atmosphere of a substrate container, a container is supported by the substrate container support and the nozzles engage the one or more gas ports of substrate container. Gas flows through the nozzles into the container interior.

As microelectronic devices become smaller and the number of microelectronic features per area of semiconductor devices increases, the devices become more sensitive to particle and environmental contaminants. With smaller microelectronic devices, contaminants having smaller and smaller sizes, even contaminants on a molecular scale, are capable of disrupting the performance of a microelectronic device. Consequently, ever-improving control of particle contamination is required during all phases of processing semiconductor substrates, including during transport of substrates between process steps.

There is ongoing need for continuously-improved systems and methods of controlling gaseous environments within substrate containers to maintain a high level of cleanliness and to avoid contaminating the substrates during handling.

### SUMMARY

During use of a substrate container, for various reasons, the gaseous atmosphere within the container interior may be replaced by a new gaseous atmosphere, i.e., “purged.” As an example, a highly pure, clean, and dry gas such as clean dry air or nitrogen (referred to as a “purge gas”) may be dispensed into a container interior to replace (i.e., displace) a previous atmosphere.

To allow this, a container may include gas ports (i.e., openings or “inlets”) through which gas can be delivered to the container interior. During a purge step, the container is supported by a substrate container support that includes nozzles that dispense a purge gas into the container through gas ports at a bottom of the container. Gas flows through the nozzles into the container interior.

The method and equipment used to fill the container with a purge gas during a purge step can affect the yield of substrates that are held by the container. The seal formed between a nozzle of a substrate container support and a purge port of a substrate container may affect the efficiency of filling the container with the purge gas. More specifically, an improved seal, with no leaking between the nozzle and the purge port, provides the best flow of the purge gas through the nozzle and into the container. The location of a nozzle that engages the purge port, including the height of the nozzle, affects the seal and the pressure of the gas flowing through the nozzle into the container. A better seal produces a higher flow pressure (“back pressure”) and a more efficient step of filling the container with the purge gas.

The present description identifies substrate container supports, systems that include a substrate container support and a substrate container, and related methods, useful to purge a substrate container. The system includes adjustable nozzles that may be moved vertically to adjust a location of a nozzle relative to a port of a substrate container, to produce an effective seal, e.g., to produce a tight seal that reduces or eliminates leaking from the seal and produces a high pressure of gas flowing through the nozzle and into a substrate container.

In one aspect, the invention relates to a substrate container support system. The system includes: a base having a horizontal base surface; a nozzle extending vertically from the base surface, the nozzle being capable of vertical movement relative to the base surface; a pressure sensor adapted to sense fluid pressure of fluid passing through the nozzle; and a control system comprising a hardware processor and a memory, the control system configured to adjust a vertical position of the nozzle based on the fluid pressure.

In another aspect the invention relates to a method of moving gaseous fluid relative to an interior of a substrate container supported by a substrate container support system. The substrate container support system includes: a base having a horizontal base surface; a nozzle extending vertically from the base surface, the nozzle being capable of vertical movement relative to the base surface; a pressure sensor adapted to measure pressure of fluid passing through the nozzle; and a control system comprising a hardware processor and memory, the control system configured to adjust a vertical position of the nozzle based on the fluid pressure. The substrate container is supported by the base and includes: an inlet port comprising a surface that engages the nozzle to form a seal between the nozzle and the inlet port. The method includes moving the nozzle to a vertical location at which the nozzle forms a desired seal with the inlet port as determined by the fluid pressure.

### BRIEF DESCRIPTION OF THE DRAWINGS

FIG. 1 is a perspective view of an example wafer container as described.

FIG. 2 illustrates a system as described.

FIG. 3A is a top perspective view of a portion of a substrate container support as described.

FIG. 3B is a top perspective view of a portion of a substrate container support as described, and a detailed view (inset) of a nozzle and nozzle adjusting device.

FIG. 3C is a bottom view of a portion of a substrate container support as described.

All figures are schematic and not to scale.

### DETAILED DESCRIPTION

The present disclosure describes support devices (e.g., a “substrate container support,” “support plate,” or “load port,” and associated equipment) that are useful with substrate containers (sometimes referred to as “substrate carriers” or “wafer containers”) used to hold or transport substrates (e.g., semiconductor wafers or the like) in a clean environment, as well as associated methods of using the support devices and substrate containers.

The substrate container includes a container body that has an interior, an opening on one side of the body to access the interior, and a door that is adapted to cover and seal the opening. The container also includes one or more gas ports, including at least one inlet port (“inlet” or “inlet port”) that is useful to dispense a gas (e.g., a “purge gas”) into the interior of the container, and one or more optional outlet ports (“outlets”).

The container can be used as a component of a system (e.g., a “substrate container system”) that includes a container support device as well as other components such as a control system and a source of raw materials (purge gases) that are used with the substrate container for handling substrates in a clean environment.

The substrate container support includes a support base (“base”) that has a horizontal base surface and at least one movable nozzle that extends vertically from the surface of the base to engage at least one inlet port of the container, while the container is supported by the substrate container support. During a purge step, the container is supported by the substrate container support, the nozzles engages the inlet port, and purge gas is dispensed through the nozzle into the container to fill the container with the purge gas and replace a previous gaseous atmosphere.

The method and equipment used to dispense purge gas into the container during a purge step can affect the yield of substrates that are held by the container. The location (height) of a nozzle of a substrate container support relative to an inlet port (or an outlet port) of a substrate container, and the seal formed between the nozzle and the inlet port, may change the effectiveness or efficiency of a purge step that dispenses the purge gas into the container. More specifically, an improved seal with minimum leaking between the nozzle and the inlet port provides improved flow of the purge gas through the nozzle and into the container. The location of a nozzle that engages the purge port, including the height of the nozzle, affects the seal between the nozzle and the inlet port, and the pressure and flow rate of purge gas flowing through the nozzle into the container. A more secure seal produces a higher flow pressure (“back pressure”) of purge gas through the nozzle and into the container, and a more efficient step of filling the container with the purge gas.

Accordingly, described herein are systems and methods that can be used to produce a high-quality, tight (substantially leak-proof) seal between a nozzle and one or more ports of a container during a purge step. Example systems include an adjustable nozzle that can be moved vertically relative to a base of a substrate container support and relative to one or more ports of a substrate container while the container is supported by the substrate container support. While the container is supported by the substrate container support, the nozzle can be moved vertically relative to the port and the quality of the seal can be assessed to identify a location of the nozzle at which a desired (e.g., optimal) seal occurs.

In preferred examples, the quality of the seal can be assessed by measuring a pressure of gas in the system at a location that reflects the pressure as the gas flows through the nozzle into the container. For example, a pressure of gas may be measured at the nozzle (within the nozzle) or at a conduit that connects to the nozzle. Based on the measured pressure, the position of the nozzle can be adjusted and the height of the nozzle relative to the base of the substrate container support may be changed to provide a high pressure of the flow of gas through the nozzle, which indicates a high quality seal.

A wafer container includes a multi-sided container body (sometimes referred to as a “shell”) that defines a container interior that is adapted to contain and support one or more semiconductor wafers. The body includes an opening (“container opening” or “opening”) that allows access to the container interior on one side of the container body. The container also includes a door that is adapted to cover the opening and form a seal over the opening between the container interior and an exterior of the container. A substrate container can typically include at least one inlet port that is adapted to allow a gas, e.g., a “purge gas,” to be delivered to the container interior, as well as at least one (optional) outlet port that allows gas from the container interior to flow out of the interior and pass to an exterior. Optionally, the container may also include one or more purge gas delivery devices, sometimes referred to as “diffusers,” connected to the inlet port. The diffuser may be used to distribute the purge gas throughout the container interior, for example by dispensing the purge gas along a length of the diffuser with the diffuser being located vertically along a height of the container interior.

The substrate container is adapted to contain multiple substrates. A “substrate” may be any of a variety of different generally flat structures that are known to be of a type that is commonly contained or transported in a substrate container device, to allow safe and clean handling and transport of the substrate without causing damage or contamination of the substrate. Example substrates include semiconductor wafers, precursors thereof, derivatives thereof, and in-process versions of any of these, including in-process semiconductor wafers, in-process microelectronic devices, EUV (extreme ultraviolet light) reticles, panels, or other structures known to be carried or contained in a carrier as described herein, any of which may be referred to generically as a “wafer” or a “substrate.”

The purge gas may be a dry gas such as clean dry air, oxygen gas, or an inert gas such as nitrogen gas. As used herein, the term “nitrogen gas” refers to pure nitrogen gas, meaning nitrogen gas that contains at least 99.9 or 99.99 percent (molar) nitrogen, and less than 0.01 or less than 0.001 percent (molar) moisture. The term “clean dry air” refers to a gaseous composition that would be considered to be clean dry air that is sufficiently pure and moisture-free to be used in a commercial step of processing a semiconductor or microelectronic substrate; this includes gases that contain approximately 78 mole percent nitrogen (N₂), and approximately 21 mole percent oxygen (O₂), and less than 0.01 or less than 0.001 percent (molar) moisture. An example of a clean dry air product is ultra-high purity extreme clean dry air (XCDA®) available from Entegris Inc., Billerica MA. The term “oxygen gas” refers to pure oxygen gas, meaning oxygen gas that contains at least 99.9 or 99.99 percent (molar) oxygen, and less than 0.01 or less than 0.001 percent (molar) moisture.

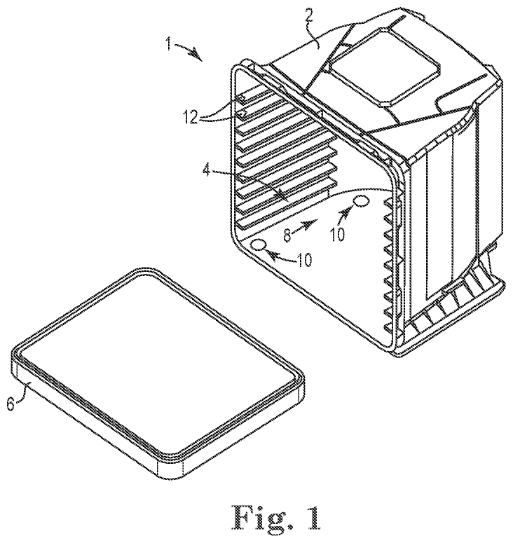

FIG. 1 shows a substrate container that can be used as a component of a system as described. Substrate container 1 includes container body (e.g. “shell”) 2, front opening 4, interior 8, ports 10 in the form of openings that pass through the bottom wall of shell 2, and slots 12 at opposite sidewalls. Slots 12 are adapted to engage and support edges of multiple substrates (not shown) as the substrates are held within interior 8. Substrate container 1 also includes door 6, which can be used to cover opening 4 to close and seal interior 8.

Substrate container 1 can be used for transporting, containing, or storing semiconductor wafers (substrates) that are being processed by a series of processing steps (i.e., wafers that are “in-process”), between steps of the series. Substrate container 1, as illustrated, is a front opening container, for example, a “front opening unified pod” or “FOUP.”

Container body 2 defines interior 8 within container 1, with opening 4 provided on one side of container body 2 to allow access to interior 8. Open side 4 allows multiple wafers to be placed inside of interior 8 of container body 2, while being supported at slots 12. Door 6 can be used to cover opening 4. When opening 4 is covered by door 6, a seal is formed by a gasket (not shown) between the door and the container. The sealed interior of container 1 is a microenvironment that is protected from contaminants that are exterior to container 1.

A substrate container as described can be used as a component of a system, e.g., a “substrate container system,” that includes the substrate container and one or more appurtenant devices that can engage the substrate container during use, such as during steps of opening or closing the substrate container, inserting substrates into or removing substrates from the container interior, adding a gaseous atmosphere to the container interior, etc. As described herein, the system includes a substrate container support that supports the container from the bottom of the container, and includes one or more nozzles to dispense a purge gas into the container through an inlet port of the container. The substrate container support may be incorporated into an apparatus referred to as a “loadport,” and may also include: one or more sources of purge gas; purge gas controls (e.g., valves) that may include flow control devices to control a volume or amount of purge gas flow, a temperature control device to control a temperature of a purge gas, mixing controls to combine two flows of different purge gases into a single purge gas mixture; measurement systems to measure or monitor a condition of the container (e.g., temperature, pressure, or humidity of a container interior or atmosphere); and a control system that communicates with the substrate container to affect or control a condition within the container or to control a condition (e.g., temperature) or flow rate of a purge gas.

The substrate container support includes one or more nozzles that engage one or more input ports of a substrate container as the container is supported by the substrate container support. The substrate container support also includes or cooperates with a source of purge gas, and is adapted to produce a flow of purge gas that flows through the nozzle to dispense the purge gas into the container interior, while the container is supported by the substrate container support. Also as described, the one or more nozzles can be moved vertically relative to the port to adjust the effectiveness of the seal between the nozzle and the port. In preferred examples, the effectiveness of the seal can be assessed by gas pressure of gas flowing through the nozzle. Based on a measured pressure of the purge gas, the position of the nozzle can be adjusted and the height of the nozzle relative to the base of the substrate container support, and the port, may be changed to provide a high pressure of the flow of gas through the nozzle.

The process of adjusting a height of a nozzle relative to a port to produce a desired seal between the nozzle and the port can involve a control system that is adapted to receive input from the system, particularly including a measured pressure value that reflects the pressure of a gas that flows through the nozzle and past the seal. With reference to a range of pressure values that indicate the quality of a seal between a particular nozzle and a particular port, a relatively higher measured pressure indicates a better seal, and a relatively lower pressure indicates a lower quality seal, which may be improved by better positioning of the nozzle relative to the port.

The pressure of the gas may be measured at any location that is useful to assess the quality of a seal between the nozzle and the port. As used herein, a pressure of gas flowing through a nozzle may be measured at a location that is within the nozzle, adjacent to the nozzle (upstream or downstream), upstream from the nozzle and within a conduit between a gas source and the nozzle, or within the substrate container, as effective to measure the quality of the seal between a nozzle and the port of a container. In response to one or a series of pressure readings performed while gas flows through a nozzle, which is engaged with a port of a substrate container to form a seal, the height of the nozzle may be adjusted. The height of one or more nozzles may be adjusted by any useful device or method steps, and is preferably adjusted using an electronically controlled height adjusting device (or “adjusting device”) such as a hydraulic device, a pneumatic device, or a mechanical device that may include a stepper motor.

An example control system may monitor and control the system using at least a computerized hardware processor with a memory device that is operatively connected to the processor. The memory can store instructions to be executed at the processor. According to various example systems, a control system can include, as a computer processor, a microprocessor of any form, e.g., a process logic controller (PLC controller) embodied in an application-specific integrated circuit (ASIC), or the like. The control system can also include a pressure sensor that measures a pressure value that reflects the pressure of a gas that flows through the nozzle and into the container, and can communicate with one or more electronically controlled height adjusting devices that can be used to move a nozzle vertically up or down in response to the measured pressure value.

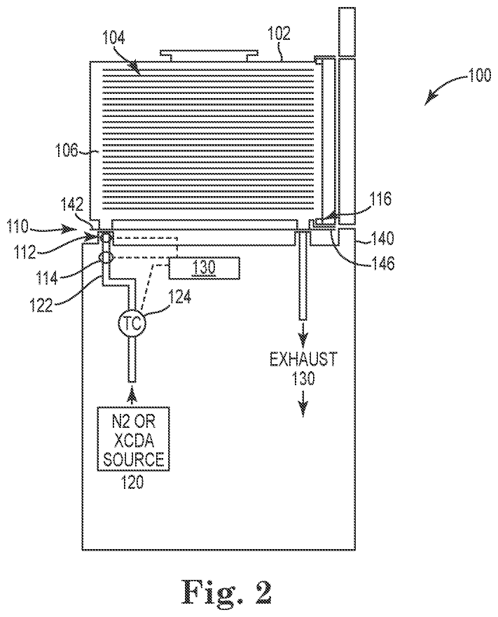

An example system is shown at FIG. 2. System 100 includes substrate container 102, which contains multiple substrates 104 held within interior 106. Container 102 includes inlet port 110 to allow gas to flow into interior 106, and optional outlet port 116 to allow gas to flow from interior 106 as exhaust 130 to an exterior of container 102. Container 102 is supported by substrate container support 140, which includes an upper plate (a.k.a. “base”) having an upper horizontal surface 142. At least one nozzle 112 extends through horizontal surface 142 to engage inlet port 110 of container 102. System 100 also includes a purge gas source 120, which may be a source of any useful purge gas such as nitrogen gas or clean dry air (e.g., “XCDA”). Flow meter and valve 124 controls a flow of the purge gas from source 120 through conduit 122, through nozzle 112, through inlet 110, and into interior 106. Container 102 also includes an opening (not shown) through one side of the container that allows for access to interior 106, and a door (not shown) that can be selectively placed over or removed from the opening.

Nozzle 112 is adjustable, i.e., is moveable vertically by use of an adjusting device (not shown) to produce an effective seal between nozzle 112 and port 110. System 100 also includes pressure gauge 114 and a control device (e.g., microprocessor) 130 that communicates with pressure gauge 114 and the adjusting device that is adapted to adjust the vertical position of nozzle 112 relative to port 110 to produce an effective seal. Control device 130 may also communicate with other devices, monitors, sensors, etc., of system 100, such as with flow meter 124 (as illustrated) and optional sensors (not illustrated) within container 102.

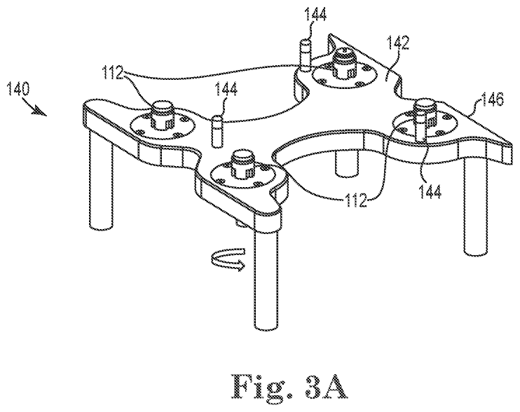

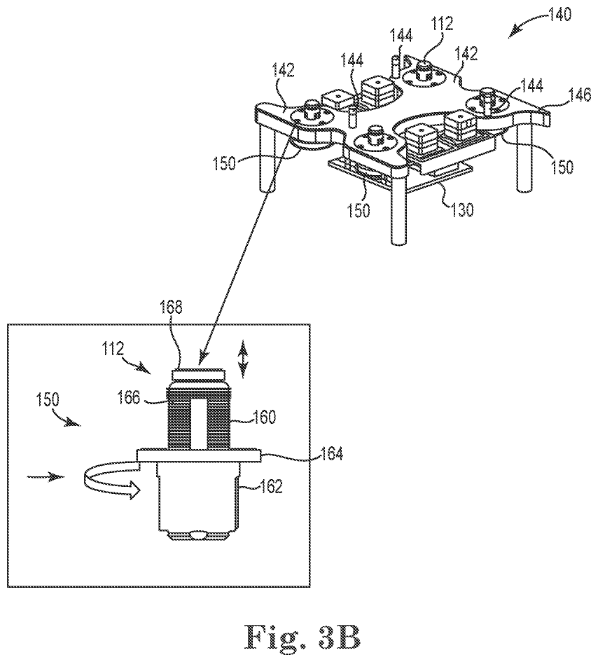

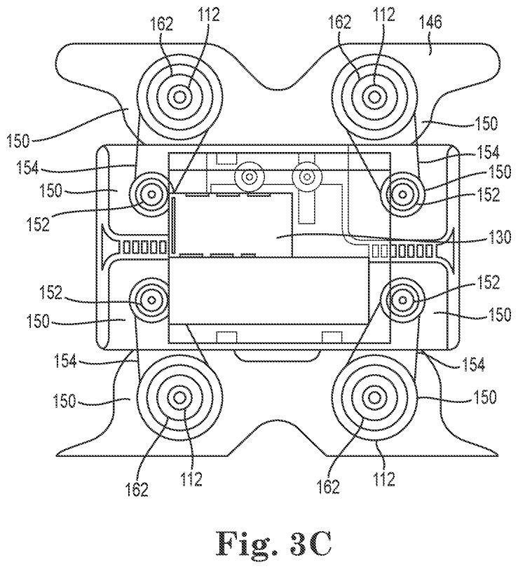

Referring to FIGS. 3A and 3B, a portion of substrate container support 140 is shown with added detail. As illustrated, substrate container support 140 includes plate (or “base”) 146 having upper surface 142. Alignment pins 144 extend vertically from surface 142 and engage alignment surfaces (e.g., apertures) of a container (not shown) that is placed to be supported by substrate container support 140. Four nozzles 112 extend above upper surface 142. At least one of nozzles 122 is an inlet nozzle that engages an inlet port of a container to dispense gas from a gas source (not shown) through the nozzle and into an interior of a container. The remaining three nozzles may be inlet nozzles or outlet nozzles. Each nozzle includes an upper surface 168, e.g., a solid or flexible grommet, that is adapted to engage an inlet (or outlet) port of a container (e.g., 120) to form a seal.

The vertical positions of nozzles 112 can be adjusted using adjusting devices 150 (see FIG. 3B), which are positioned below plate 146, and are engaged with each of nozzles 112. As illustrated, the system includes one adjusting device 150 for each nozzle 112, and the vertical position of each nozzle 112 can be adjusted independently of the other nozzles. In other example systems, a single adjusting device 150 may be connected to two or more nozzles, to adjust the two or more nozzles simultaneously.

At FIG. 3B, inset, is illustrated an example of a portion of an adjusting device 150 useful to adjust a height of nozzle 112 vertically. Adjusting device 150 includes body 160, threaded outer surface 166, flange 164, and threaded outer fitting 162. Threaded outer fitting 162, e.g., in the form of a nut, includes a threaded inner surface that engages threaded outer surface 166 of body 160. Threaded outer fitting 162 can be held in a vertically stationary position relative to flange 164 such that rotation of threaded outer fitting 162 about body 160 causes body 160, valve 112, and surface 168, to move vertically upward or downward relative to flange 164 and surface 142 depending on the direction of rotation of threaded outer fitting 162.

In use, body 160 passes through an opening in plate 146 and may be secured to plate 146 at flange 164. A container 120 is placed above upper surface 142 and contacts and rests on one or more of alignment pins 144, nozzles 112, or surface 142, with nozzle 112 and surface 168 being aligned to engage a port of container 120. The vertical location of nozzle 112 and the quality (degree of air tight-ness of the seal) of a seal between nozzle 112 (at surface 168) and a port of the container can be monitored by monitoring a pressure within the system that indicates the pressure of gas within nozzle 112 as gas flows through nozzle 112, and the presence or absence of a leak at the seal. For a given valve and port, a higher pressure indicates a tighter seal and a lower pressure indicates a less tight seal. According to methods as described, generally, the vertical location of the nozzle may be adjusted up or down to achieve a high or maximum pressure within nozzle 112, meaning a desired seal with substantially no leaking of gas at the seal.

FIG. 3C shows a detailed bottom view of example substrate container support 140. Located at positions beneath plate 146 are control system 130, stepper motors 152 and lower portions of nozzles 112, including threaded outer fittings 162 engaged with lower portions of body 160. To adjust the vertical position of one or more nozzles 112, control system 130 communicates with a stepper motor 152, connected to threaded outer fittings 162 by belts 154, to rotate outer fitting 162 about threaded outer surface 166 of outer body 160 of nozzle 112.

While the present description exemplifies, and the figures illustrate an example of a mechanical adjusting device that includes a threaded engagement to control the movement of nozzles up and down, other mechanical engagements may also be used, such as mechanical engagements that use a non-threaded engagement such as a gear. Still other examples of useful adjusting devices may be pneumatic or hydraulic. A pneumatic adjusting device uses pressurized gas (e.g., air) that can be added to or removed from a space that contacts a moveable valve, to move the valve. A hydraulic adjusting device uses pressurized liquid that can be added to or removed from a space that contacts a moveable valve, to move the valve.

The system can be used to produce a desired high-quality, fluid-tight seal between a nozzle and one or more ports of a container during a purge step. According to example methods, a substrate container is lowered vertically, from above, onto a substrate container support. Alignment pins of the support engage alignment surfaces (e.g., apertures) located at the bottom of the container to set the horizontal (lateral, front-to-back and side-to-side along length and width) orientation of the container relative to the horizontal upper surface of the support. Nozzles of the support align with ports of the container. The container may be supported by the upper surface of the substrate container, or by one or more of the alignment pins engaging the alignment surfaces of the container, or by the upper surface of one or more nozzles contacting a port of the container. Generally, gas is caused to flow through one or more nozzles and a pressure that is indicative of the pressure of the gas flowing through the one or more nozzles is be measured. The vertical position of the one or more nozzles can be adjusted based on the measured pressure until a desired high pressure is achieved, indicating a tight seal.

The system can identify a final position of the nozzle used for performing a purge step by various criteria. As an example, the system may set a final position of a nozzle based on a set “target” pressure that has been pre-determined for a particular set of a nozzle and a container. For example, the system may raise or lower a position of the nozzle to achieve an expected target pressure. As another example, the system may set a final position of a nozzle by identifying a constant (plateau) or a maximum pressure achieved by the system. During a purge step, the system may continue to monitor pressure through the nozzle and optionally may adjust the vertical position of the nozzle during a purge step.

According to example steps, a substrate container is lowered vertically from above onto the substrate container support. The container and support are aligned laterally using the alignment pins of the support and the opposed alignment surfaces of the container. Gas is caused to flow through the nozzles and into the container. Movable nozzles of the substrate container support are raised to engage the ports of the substrate container and to lift the container to a position of being supported by the one or more nozzles without being supported by the alignment pins. This position, with nozzles supporting the container, may produce a maximum pressure reading (“target pressure”) of the gas flow and a best or optimal seal, e.g., a nozzle position that does not allow leaking of gas through the seal. The vertical position of the nozzles can be lowered and the pressure of the gas flowing through the nozzle can be measured, e.g., continuously, and preferably at a location within the nozzle or slightly upstream from the nozzle. With the pressure being monitored, one or more nozzles (individually or together) may be lowered to a lowest position at which the gas flow pressure remains at or near the target (e.g., maximum) pressure. Preferably but not necessarily the nozzles can be lowered to a position at which the alignment pins contact the alignment surfaces of the container to support the container, while the pressure remains at the maximum or target pressure, and a purge step can be performed.

1. A substrate container support system comprising:
a base having a horizontal base surface;
a nozzle extending vertically from the base surface, the nozzle being capable of vertical movement relative to the base surface;
a pressure sensor adapted to sense fluid pressure of fluid passing through the nozzle; and
a control system comprising a hardware processor and a memory, the control system configured to adjust a vertical position of the nozzle based on the fluid pressure.

2. The system of claim 1, comprising a gas source, a conduit to pass gas from the gas source to the nozzle, wherein the pressor sensor is located within the conduit to sense fluid pressure of the gas within the conduit as gas flows through the conduit and nozzle.

3. The system of claim 2, wherein:
the nozzle comprises a nozzle body having a threaded surface,
the system comprises a threaded fitting that engages the threaded surface, and
the nozzle can be moved vertically by rotating the threaded fitting relative to the nozzle body threaded surface.

4. The system of claim 3, comprising a stepper motor adapted to rotate the threaded fitting to cause vertical movement of the nozzle.

5. The system of claim 4, wherein the control system comprises pressurized fluid that engages the nozzle to control a vertical position of the nozzle.

6. The system of claim 1, comprising two nozzles that include a first nozzle extending vertically from the base surface and capable of vertical movement relative to the base surface, and a second nozzle extending vertically from the base surface and capable of vertical movement relative to the base surface, wherein at least one of the nozzles is an input nozzle adapted to allow gas to flow from a gas source into a substrate container.

7. The system of claim 6, wherein the control system comprises adjusting means for vertically moving the first nozzle and the second nozzle, the adjusting means being adapted to vertically move the nozzles.

8. The system of claim 6, wherein the control system comprises adjusting means for vertically moving the first nozzle and the second nozzle, the adjusting means being adapted to vertically move the first nozzle and the second nozzle together.

9. The system of claim 6, wherein the control system comprises adjusting means for vertically moving the first nozzle and the second nozzle, the adjusting means being adapted to vertically move the first nozzle and to independently move the second nozzle.

10. The system of claim 9, comprising a solid seal surface or a deformable seal surface at an upper end of the nozzle.

11. The system of claim 10, comprising a substrate container supported by the substrate container support, the substrate container comprising an inlet port, the inlet port comprising a surface that engages the nozzle to form a seal between the nozzle and the inlet port.

12. The system of claim 11, wherein the base comprises a plurality of alignment pins extending vertically from the base, wherein each alignment pin contacts an alignment surface of the substrate container to align the substrate container with the base.

13. The system of claim 12, wherein the control system is adapted to move the nozzle to a vertical position at which the nozzle forms a seal with the fluid passage as determined by a maximum fluid pressure.

14. The system of claim 13, wherein the substrate container is a front-opening unified pod.

15. A method of moving gaseous fluid relative to an interior of a substrate container supported by a substrate container support system, the substrate container support system comprising:
a base having a horizontal base surface;
a nozzle extending vertically from the base surface, the nozzle being capable of vertical movement relative to the base surface;
a pressure sensor adapted to measure pressure of fluid passing through the nozzle; and
a control system comprising a hardware processor and memory, the control system configured to adjust a vertical position of the nozzle based on the fluid pressure,
a substrate container supported by the base, the substrate container comprising an inlet port, the inlet port comprising a surface that engages the nozzle to form a seal between the nozzle and the inlet port,
the method comprising moving the nozzle to a vertical location at which the nozzle forms a desired seal with the inlet port as determined by the fluid pressure.

16. The method of claim 15, wherein forming the fluid-tight seal comprises:
moving the nozzle vertically to cause the nozzle to engage the fluid passage surface,
passing fluid through the nozzle,
measuring the fluid pressure within the nozzle, and
adjusting the vertical position of the nozzle to produce a desired fluid pressure.

17. The method of claim 16, wherein the pressure is measured upstream from the nozzle.

18. The method of claim 17, wherein forming the fluid-tight seal comprises:
moving the nozzle vertically to cause the nozzle to engage the inlet port,
measuring a maximum pressure within the nozzle, and
performing a purge step while maintaining a vertical position of the nozzle with the maximum pressure.

19. The method of claim 18, wherein:
the base comprises a plurality of alignment pins extending vertically from the base, each alignment pin having a tip at an end, and each tip contacts a bottom surface of the substrate container to support the substrate container.
